(19) United States
(12) Patent Application Publication
(10) Pub. No.: US 2023/0176098 A1
(43) Pub. Date: Jun. 8, 2023

(54) METERING DEVICE WITH BACKUP POWER FOR SYSTEM MONITOR

(71) Applicant: FLORIDA POWER & LIGHT COMPANY, JUNO BEACH, FL (US)

(72) Inventors: Guillermo Aleman, Miami, FL (US); Kathryn Stutin, Plantation, FL (US); Eliud Perez, Royal Palm Beach, FL (US); Dale W. Lange, Edmonds, WA (US)

(73) Assignee: FLORIDA POWER & LIGHT COMPANY, JUNO BEACH, FL (US)

(21) Appl. No.: 17/545,524

(22) Filed: Dec. 8, 2021

(51) Int. Cl. G01R 21/133

(52) U.S. Cl. CPC G01R 21/1333

(57) ABSTRACT

A metering device for monitoring power flow at a premises includes a metering module that measures power flow on powerlines at a premises and provides power flow data characterizing the power flow on the powerlines. The metering device also includes a communication module coupled to the metering module that transmits power flow data to a node on a meter network. The metering device further includes an energy storage element coupled to the metering module and the communication module. The energy storage element provides backup power to the metering module and the communication module in response to a voltage on the powerlines dropping below a first threshold for a time interval exceeding a second threshold, such that the metering module measures the power flow on the powerlines and provide the power flow data for a backup interval of time.

### TECHNICAL FIELD

The present disclosure relates to a metering device with an energy storage element to provide backup power to enable measurement of power during a power loss event.

### BACKGROUND

A smart meter or smart meter collar is an electronic device that records information such as consumption of electric energy, voltage levels, current and power factor. Smart meters and smart meter collars communicate the information to the consumer for greater clarity of consumption behavior, and electricity suppliers for system monitoring and customer billing. Smart meters and smart meter collars record energy near real-time, and report regularly, for short intervals throughout the day. Smart meters and smart meter collars enable two-way communication between the meter and the central system. Such an advanced metering infrastructure (AMI) differs from automatic meter reading (AMR) in that it enables two-way communication between the meter and the supplier. Communications from the meter to the network may be wireless, or via fixed wired connections such as power line carrier (PLC). Wireless communication options in common use include cellular communications, Wi-Fi (readily available), wireless ad hoc networks over Wi-Fi, wireless mesh networks, low power long-range wireless (LoRa), Wize (high radio penetration rate, open, using the frequency 169 MHz) ZigBee (low power, low data rate wireless), and Wi-SUN (Smart Utility Networks).

Ride-through capability is the ability of a power source to deliver usable power for a limited time during a power loss. The short loss of power causes computers and other sensitive electrical equipment to shut down hard, damaging circuits and increase maintenance costs. Computer Business Equipment Manufacturers Association (CBEMA) curve is a commonly employed power acceptability curve. The CBEMA curve was originally derived to describe the tolerance of mainframe computer business equipment to the magnitude and duration of voltage variations on the power system. The tolerance of data-processing equipment to voltage variations is often characterized by the CBEMA curve, which give the duration and magnitude of voltage variations that are to be tolerated. Stated differently, the CBEMA curve defines a standard ride through requirement for power equipment.

### SUMMARY

One example relates to a metering device for monitoring power flow at a premises. The metering device includes a metering module that measures power flow on powerlines at a premises and provides power flow data characterizing the power flow on the powerlines. The metering device also includes a communication module coupled to the metering module that transmits power flow data to a node on a meter network. The metering device further includes an energy storage element coupled to the metering module and the communication module. The energy storage element provides backup power to the metering module and the communication module in response to a voltage on the powerlines dropping below a first threshold for a time interval exceeding a second threshold, such that the metering module is configured to measure the power flow on the powerlines and provide the power flow data for a backup interval of time following the voltage dropping below the first threshold for a time exceeding the second threshold.

Another example relates to a system for monitoring power flow at a plurality of premises. The system includes a meter network having a plurality of metering devices that each include an energy storage element coupled to a metering module and a communication module. The energy storage element provides backup power to the metering module and the communication module in response to a voltage on corresponding powerlines dropping below a first threshold for a time interval exceeding a second threshold, such that the metering module of a respective metering device of the plurality of metering devices is configured to measure the power flow at a respective premises and provide power flow data characterizing the measured power flow for a backup interval of time following the voltage dropping below the first threshold for the time interval exceeding the second threshold and the communication module transmits the power flow data to a node on the meter network during the backup interval of time. The system also includes a utility server coupled to the meter network that receives the data from each of the plurality of metering devices.

Yet another example relates to a method for monitoring power flow at a premises. The method includes measuring, by a metering module of a metering device that communicates on a meter network, a first power flow characterizing power on powerlines for a premises that characterizes power consumption by the premises. The method also includes detecting, by the metering device, a drop in a voltage on the powerlines to a level less than a first threshold for an interval of time exceeding a second threshold and providing, from an energy storage element to the metering device, backup power to the metering module and a communication module of the metering device in response to the detecting. The method further includes measuring, by the metering module, a second power flow on the powerlines during a backup interval of time following the voltage dropping below the first threshold for the interval of time exceeding the second threshold. The method still further includes transmitting, by the communication module, power flow data characterizing the second power flow measured by the metering module to a node on a meter network during the backup interval of time following the voltage dropping below the first threshold for the time interval exceeding the second threshold.

### BRIEF DESCRIPTION OF THE DRAWINGS

FIG. 1 illustrates an example of a metering device that supplies backup power to a system monitor for measuring power on powerlines.

FIG. 2 illustrates a block level circuit diagram of a metering device that supplies backup power to a system monitor for measuring power on powerlines.

FIG. 3 illustrates an example of a system that includes a metering device communicating on a utility network.

FIG. 4 illustrates a flowchart of an example method for monitoring power flow at a consumer premises during a power loss event.

### DETAILED DESCRIPTION

This disclosure relates to a metering device that measures power flow on a power line after supplied power on the power line drops below a first predetermined threshold for a time interval exceeding a second predetermined threshold. More particularly, the metering device is a smart device that includes a monitoring system coupled to an energy storage element (e.g., a capacitor or a battery) that operates as a backup power source. In some examples, the metering device is a smart meter installable in an inlet port of a metering box at a customer premises. In other examples, the metering device is a smart meter collar installable between an electric meter and the inlet port at the customer premise. However, in every such example, the operations are the metering device (a smart meter or a smart meter collar) are similar. The monitoring system includes a communication module (circuit) and a metering module (circuit). Accordingly, if supplied power to the metering device drops below the first predetermined threshold for a time exceeding the second predetermined threshold, in the event of a power loss event (e.g., a blackout or brownout), the energy storage device discharges to supply backup power to the system monitor, including both the communication module and the metering module. Therefore, the metering module can measure power flow (e.g., current and voltage, power and power factor or some combination thereof) and the communication circuit can transmit data characterizing the power flow during an interval of time after the voltage on the power line drops below the first predetermined threshold for a time interval longer than the second predetermined threshold, which interval of time is referred to as a back up interval of time.

In some examples, the first predetermined threshold (e.g., a voltage level) and the second predetermined threshold (e.g., an interval of time) can be defined with the Computer and Business Equipment Manufacturers Association (CBEMA) curve that defines power acceptability of supplied power. Accordingly, power supplied to the metering device is below the first predetermined threshold for a time interval longer than the second predetermined threshold defined by the CBEMA curve can indicate an outage or loss of power supplied to the metering device. In the event of an outage or when supplied power is below a predetermined threshold (e.g., a blackout or a brownout), an energy storage element, such as a capacitor can be discharged to power the communication circuit of the metering device (e.g., a smart meter or a smart meter collar) to transmit data characterizing power consumption. Accordingly, during the backup interval of time, the metering device can measure power flow on the power lines and transmit power flow data characterizing the power flow after supplied power is below the first predetermined threshold.

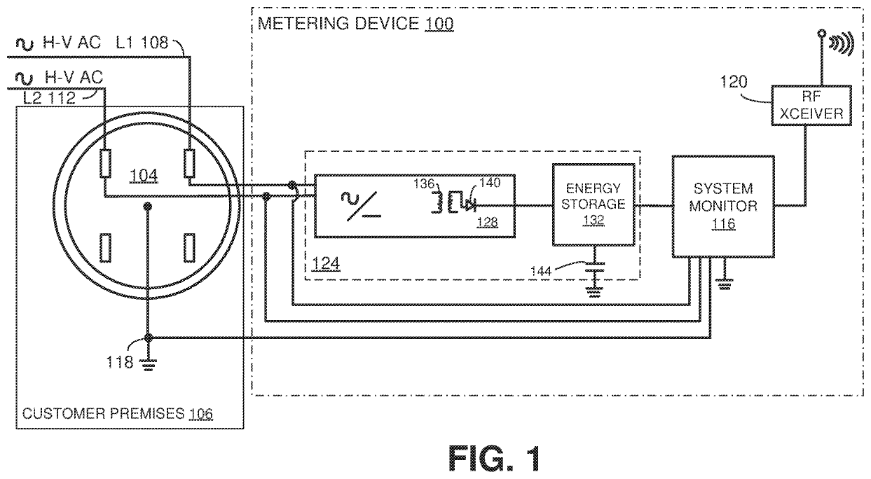

FIG. 1 illustrates an example of a metering device 100 coupled to an inlet port 104 for a customer premises 106 (e.g., a residence or a business) that consumes electricity. In some examples, the metering device 100 is a smart meter insertable into the inlet port 104 of a metering box at the customer premises 106. In other examples, the metering device is a smart meter collar installable between an electric meter and the inlet port 104 at the customer premise 104. However, in every such example, the operations are the metering device 100 (a smart meter or a smart meter collar) are similar. The inlet port 104 is coupled to two powerlines, namely the lines L1 108 and L2 112. Lines L1 108 and L2 112 are coupled to a transformer of a power grid. L1 108 and L2 112 are configured to carry a high voltage (H-V) alternating current (AC) signal that are 180 degrees out of phase. In some examples, such as in regions of the United States, both L1 108 and L2 112 are configured to carry a 120 Volt (V) AC signals that are 180 degrees out of phase. In other regions (e.g., Europe), L1 108 and L2 112 carry different voltages.

The metering device 100 includes a system monitor 116 configured to periodically and/or asynchronously measure a power flow (e.g., with a voltage measurement) on the Lines L1 108 and L2 112 and output power flow data to a radio frequency (RF) transceiver 120. In some examples, the system monitor 116 is also coupled to an electrically neutral node 118 (e.g., earth ground) provided at the inlet port 104. In other examples, the system monitor 116 (and the metering device 100, more generally) is ungrounded. The RF transceiver 120 modulates the data on an RF signal that is provided to a node on a utility network (e.g., another metering device or data ingress port). The RF transceiver 120 can be a Wi-Fi transceiver, a Bluetooth transceiver, or a cellular radio transceiver. For instance, in some examples, the utility network can include a meter mesh network. Conversely, in some examples, the node on the utility network (e.g., in response to a command from another node on the utility network) can poll the metering device 100 through the RF transceiver 120 for the data characterizing the measured voltage on the lines L1 108 and L2 112. In response to this poll, the system monitor 116 measures the power flow (e.g., with a voltage measurement) on the lines L1 108 and L2 112 and transmits data to the RF transceiver 120, wherein the data is wirelessly propagated to the node on the utility network.

The metering device 100 also includes a power module 124 that is coupled to the lines L1 108 and L2 112. The power module 124 includes an AC-to-direct current (DC) converter 128 and an energy storage module 132. The AC-to-DC converter 128 is coupled to the lines L1 108 and L2 112 and converts the AC voltage on the lines L1 108 and L2 112 to a DC voltage sufficient to power circuits, such as integrated circuit (IC) chips of the system monitor 116. More specifically, the AC-to-DC converter 128 includes a step-down transformer 136 coupled to a rectifier 140 (illustrated as a diode). The AC-to-DC converter 128 outputs a DC voltage, VCC (voltage common collector) to power the system monitor 116. In some examples, VCC is about 3-12 V DC.

The energy storage module 132 includes a capacitor 144 (or other energy storage element, such as a battery) that stores DC voltage output by the AC-to-DC converter 128. The energy storage module 132 is configured to charge and to provide smoothing of the DC signal during times where the voltage on the lines L1 108 and L1 12 are at or above a predetermined voltage threshold or intervals of time wherein the voltage on the lines L1 108 and L2 112 drop below the predetermined threshold voltage (e.g., a first threshold) for a time interval below a predetermined interval of time (e.g., a second threshold). In some examples, the predetermined threshold voltage and the predetermined interval of time are thresholds defined in the CBEMA curve.

More particularly, the CBEMA curve standardizes an amount of power fluctuation a power supply needs to be able to accommodate before an output voltage drops. As an example, the predetermined threshold voltage defined in the CBEMA curve could be 90% of a predefined input voltage, and the predetermined amount of time could be 500 milliseconds. In other examples, other ranges for the thresholds in the CBEMA curve are employable. Thus, continuing with this example, a power supply that complies with the CBEMA curve will continue to output power sufficient to supply downstream components as long as the incoming power is at least 90% the predefined input voltage (e.g., 108 V for L1 104 and L2 108) or if the input voltage drops below 90% of the predefined input voltage for less than 500 milliseconds.

The metering device 100 is configured to exceed the operational parameters set forth in the CBEMA curve. More particularly, the energy storage module 132 and the capacitor 144 are sized to provide backup power to the system monitor 116 if the voltage at the lines L1 108 and L2 112 drop below the predefined threshold voltage (e.g., 90% of 120 V) for an interval of time exceeding the predetermined threshold interval of time (e.g., 500 milliseconds). Stated differently, the energy storage element 232 detects the drop in power, and in response to this drop of power, the energy storage module 132 provides the system monitor 116 with backup power. This backup power is sufficient to maintain the output DC voltage, VCC of the power module 124 for a backup interval of time. The backup interval of time ranges from about 1 second to about 20 minutes. Unless otherwise stated, in this description, ‘about’ preceding a value means +/−10 percent of the stated value.

During the backup interval of time, the system monitor 116 periodically and/or asynchronously measures a power flow (e.g., measures voltage and/or current) on the lines L1 108 and L2 112 and provides power flow data characterizing the power flow (e.g., voltage, current, power, power factor, or a combination thereof) to the RF transceiver 120, wherein this data is transmitted to a node on the utility network. The power flow data during the backup interval of time characterizes a voltage signature of the power provided through the powerlines, namely lines L1 108 and L2 112. Conversely, in some examples, during the backup interval of time, the node on the utility network (e.g., in response to a command from another node on the utility network) can poll the metering device 100 through the RF transceiver 120 for the power flow data characterizing the measured voltage on the lines L1 108 and L2 112. In response to this poll, the system monitor 116 measures the power flow (e.g., with a voltage measurement) on the lines L1 108 and L2 112 and transmits data to the RF transceiver 120, wherein the data is wirelessly propagated to the node on the utility network. In some examples, during the backup interval of time, multiple measurements of the voltage on lines L1 108 and L2 112 are recorded and transmitted to the node on the utility network.

During a power outage (e.g., blackout), the voltage on the lines L1 108 and L2 112 will be about 0 V during the backup interval of time. In other examples, during the backup interval of time, the voltage on the lines L1 108 and L2 112 may be greater than 0 V, but also less than the predetermined threshold voltage. For instance, in various examples, during a brownout, the voltage on the lines L1 108 and L2 112 may be about 10 V to about 100 V. Accordingly, the measurements taken by the system monitor 116 are employable by a node on the utility network (e.g., a server) to determine areas of a region that are experiencing reduced voltage. In conventional systems, backup power is insufficient to enable a metering device to measure voltage on a powerline. Instead, in conventional systems, after the power drops below the predetermined threshold for a time interval exceeding the predetermined threshold (e.g., set by the CBEMA curve) measurements of the voltage will only resume after power has been restored to the predetermined threshold.

By employment of the metering device 100, during power loss events, including blackouts and brownouts, an accurate measurement and/or derivation of voltage, current, power, power factor or a combination thereof on the lines L1 108 and L2 112 is recorded. Thus, deploying the metering device 100 (e.g., as smart meters, smart meter collars or some combination thereof) enables a node on the utility network to accurately determine which regions of a power grid are receiving full power (e.g., a voltage on the lines L1 108 and L2 112 meeting the predetermined threshold), no power (e.g., a voltage of about 0 V on the lines L1 108 and L2 112) or reduced voltage (e.g., voltage of greater than 0 V and less than the predetermined threshold on the lines L1 108 and L2 112).

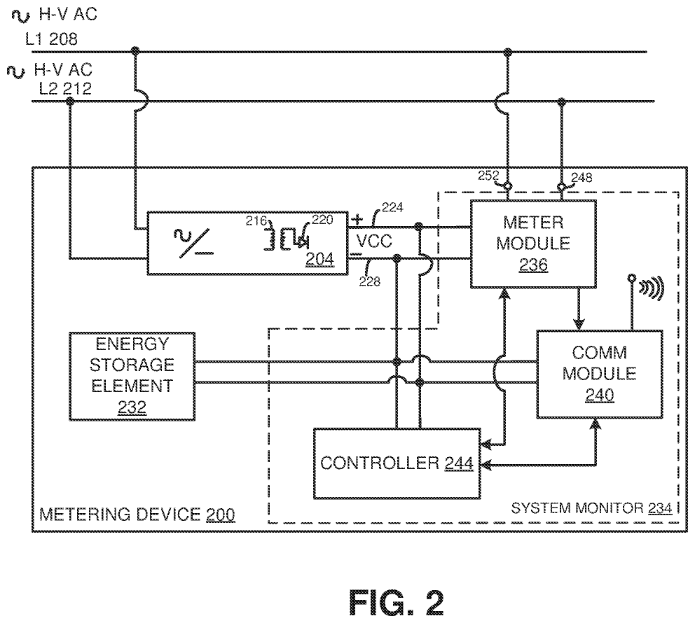

FIG. 2 illustrates a block level circuit diagram of a metering device 200. In some examples, the metering device 200 is implemented with a smart meter installed at an inlet port of a meter box at a premises. The metering device 200 is employable to implement the metering device 100 of FIG. 1. The smart meter 200 is upstream from an inlet port (e.g., the inlet port 104 of FIG. 1) that is mounted at a customer premises (e.g., a residence or a business) and downstream from a transformer that provides power to the customer premises. The metering device 200 includes a power supply module 204 that is coupled to powerlines, namely lines L1 208 and L2 212. Similar to the lines L1 108 and L2 112 of FIG. 1, the lines L1 208 and L2 212 are configured to carry a high voltage AC signal for the consumer premises.

The power supply module 204 includes an AC-to-DC converter formed with a step-down transformer 216 coupled to a rectifier 220. In some examples, the rectifier is implemented as a diode. The power supply module 204 receives the AC signal on the lines L1 208 and L2 212 and converts the AC signal to output a DC voltage of VCC (e.g., 3-12 V DC) between a positive node 224 and a negative node 228.

The positive node 224 and the negative node 228 provide the DC voltage of VCC to other components of the metering device 200. More specifically, the metering device 200 includes an energy storage element 232 coupled to the positive node 224 and the negative node 228. In some examples, the energy storage element 232 is implemented with a capacitor. In other examples the energy storage element 232 is implemented with a battery. In still other examples, the energy storage element 232 is implemented with a combination of a capacitor and a battery.

The metering device 200 includes a system monitor 234 that is employable to implement the system monitor 116 of FIG. 1. The system monitor 234 is coupled to the positive node 224 and the negative node 228. More specifically, the system monitor 234 includes a meter module 236, a communication module 240 and a controller 244 that are also coupled to the positive node 224 and the negative node 228. The meter module 236, the communication module 240 and the controller 244 are each implemented with integrated circuit (IC) chips.

The meter module 236 includes a first high impedance port 248 and a second high impedance port 252. The first high impedance port 248 is coupled to the first line L1 208 and the second high impedance port 252 is coupled to the second line L2 212. The meter module 236 is configured to measure a voltage at the first line L1 208 and the second line L2 212. In some examples, the measurements are taken periodically and/or asynchronously, such as in response to a command from the controller 244. Additionally or alternatively, the meter module 236 can be configured to also measure current flow through L1 208 and L2 212 via the use of current transformers (CTs) installed on the first high impedance port 252 and the second high impedance port 248 (or on other ports). In such an example, the current transformers are employable to measure current on the powerlines L1 208 and L2 212. Thus, in such examples, the meter module can measure and/or derive current and voltage, power and power factor, or some combination thereof.

The controller 244 is implemented as a computing device, such as a processor with embedded instructions. In some examples, the controller 244 controls operations of the meter module 236 and the communication module 240. The communication module 240 includes an RF transceiver, such as the RF transceiver 120 of FIG. 1. The communication module 240 can include a Wi-Fi transceiver, a Bluetooth transceiver or a cellular radio transceiver. The communication module 240 is configured to wirelessly communicate with a node (or multiple nodes) on a utility network. In some examples, the communication module 240 receives power flow data from the meter module 236 characterizing the voltage measured by the meter module 236 and modulates this power flow data onto an RF signal that is propagated to the node on the utility network.

Additionally, in some examples, the node on the utility network polls the metering device 200 through the communication module 240 for power flow data. In such an example, the communication module 240 forwards the poll to the controller 244. In response to the poll, the controller 244 commands the meter module 236 to measure the voltage and/or current on the lines L1 208 and L2 212. Responsive to this command, the meter module 236 measures the voltage and/or current on the lines L1 208 and L2 212 and provides power flow data characterizing the measured voltage, the measured current, a power, a power factor or some combination thereof to the communication module 240. In response, the communication module 240 modulates this data on an RF signal and provides a response to the poll.

The energy storage element 232 is configured to provide smoothing of the DC signal during times where the voltage on the lines L1 208 and L2 212 is at or above a predetermined threshold or intervals of time wherein the voltage on the lines L1 208 and L2 212 has fallen below the predetermined threshold voltage (e.g., a first threshold) for a time interval below a predetermined interval of time (e.g., a second threshold). Additionally, during time intervals that the voltage on the lines L1 208 and L2 212 is above the predetermined threshold voltage, the energy storage element 232 can charge to enable the energy storage element 232 to release stored power at a later time. In some examples, the predetermined threshold voltage and the predetermined interval of time are thresholds defined in the CBEMA curve.

The metering device 200 is configured to exceed the operational parameters set forth in the CBEMA curve. More particularly, the energy storage element 232 is sized to provide backup power to the meter module 236, the communication module 240 and the controller 244 if the voltage at the lines L1 208 and L2 212 drop below the predefined threshold voltage (e.g., 90% of 120 V) for an interval of time exceeding the predetermined threshold (e.g., 500 milliseconds). That is, the energy storage element 232 detects the drop in power, and in response to this drop of power, the energy storage element 232 provides the backup power to the meter module 236, the communication module 240 and the controller 244. This backup power is sufficient to maintain the output DC voltage, VCC of the power supply module 204 for a backup interval of time. The backup interval of time ranges from about 1 second to about 20 minutes. Furthermore, the rectifier 220, such as a diode of the power supply module 204 prevents backflow of the power stored in the energy storage element 232 from reaching the lines L1 208 and L2 212 during the backup interval of time.

During the backup interval of time, the controller 244 can command the meter module 236 to periodically and/or asynchronously measure the voltage and/or current on the lines L1 208 and L2 212 and provide power flow data characterizing the measured voltage, current, power, power factor or some combination thereof to the communication module 240, wherein this data is transmitted to a node on the utility network. Conversely, in some examples, during the backup interval of time, the node on the utility network (e.g., in response to a command from another node on the utility network) can poll the metering device 200 through the communication module 240 for the power flow data characterizing the measured voltage on the lines L1 208 and L2 212. In response, the communication module 240 provides the poll to the controller 244. Responsive to the poll from the communication module 240, the controller 244 commands the meter module 236 to measure the power flow (e.g., voltage) on the lines L1 208 and L2 212 and transmit data to the communication module 240, wherein the data is wirelessly propagated to the node on the utility network. In some examples, during the backup interval of time, multiple measurements and/or derivations of the voltage, current, power, power factor or a combination thereof on lines L1 208 and L2 212 are recorded and transmitted as power flow data to the node on the utility network in a similar manner. Thus, the power flow data during the backup interval of time characterizes a voltage signature of the power provided through the powerlines, namely lines L1 208 and L2 212.

During a power outage (e.g., a blackout), the voltage on the lines L1 208 and L2 212 will be about 0 V during the backup interval of time. In other examples, during the backup interval of time, the voltage on the lines L1 208 and L2 212 may be greater than 0 V, but also less than the predetermined threshold voltage. For instance, in various examples during a brownout, the voltage on the lines L1 208 and L2 212 may be about 10 V to about 100 V. Accordingly, the measurements taken by the meter module 236 are employable by a node on the utility network (e.g., a server) to determine regions of a power grid that are experiencing reduced voltage. In conventional systems, backup power is insufficient to enable a metering device (e.g., a smart meter or a smart meter collar) to measure voltage on an incoming powerline. In such conventional systems, only a communication module is provided power during a power loss event (e.g., a blackout or a brownout). Thus, in conventional systems, after the power drops below the predetermined threshold for a time interval exceeding the predetermined threshold (e.g., set by the CBEMA curve) measurements of the voltage will only resume after power has been restored to the predetermined threshold. Moreover, even in systems where backup power to the communication module is provided, during a power loss event, new measurements of the voltage of power lines are not taken.

By employment of the metering device 200, during power loss events, including blackouts and brownouts, an accurate measurement of voltage and/or current on the lines L1 208 and L2 212 is recorded during the backup interval of time. Thus, deploying the metering device 200 enables a node on the utility network to accurately determine which regions of a power grid are receiving full power (e.g., a voltage on the lines L1 208 and L2 212 meeting the predetermined threshold), no power (e.g., a voltage of about 0 V on the lines L1 208 and L2 212) or reduced voltage (e.g., voltage of greater than 0 V and less than the predetermined threshold on the lines L1 208 and L2 212).

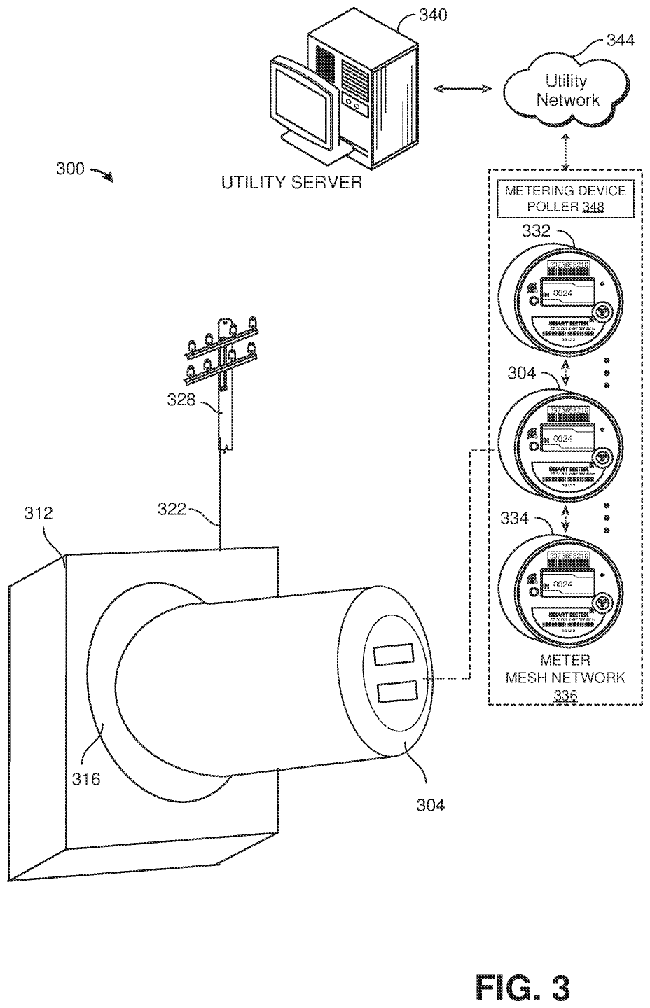

FIG. 3 illustrates an example of a system 300 that includes a metering device 304 as the metering device 100 of FIG. 1 and/or the metering device 200 of FIG. 2. Thus, the metering device 300 is representative of a smart meter or a smart meter collar. The metering device 304 can include an RF transceiver that is implemented as a Wi-Fi transceiver, a Bluetooth transceiver or a cellular radio transceiver.

The metering device 304 is configured for installation in a meter box 312, such as in a meter socket 316 of the meter box 312. The meter box 312 can be installed at a premises (e.g., one of a plurality of premises). The meter box 312 can be connected to powerlines 322 (a single line represents multiple powerlines) that is supplied from a utility pole 328 (or other source) to supply power to the premises. The metering device 304 can be implemented as a computing platform. For example, the metering device 304 can include a controller (e.g., the controller 244 of FIG. 2) implemented as a processor with machine executable instructions embedded in a non-transitory memory to control operations of the metering device 304.

The metering device 304 can communicate with other metering devices 332 and 334 on a meter mesh network 336. The metering devices on the meter mesh network 336 can be smart meters, smart meter collars or a combination thereof. The metering devices 332 and 334 and metering device 304 on the meter mesh network 336 can collect power flow data and provide the collected power flow data to a utility server 340 via a utility network 344 (e.g., a private network). In some examples, a metering device poller 348 (e.g., a node on the meter mesh network 336 and/or the utility network 344) can be employed to poll a given metering device 332 on the meter mesh network 336. In response, the given metering device 332 can poll the other metering devices, namely, the metering devices 304 and 334 for power flow data. The power flow data can be provided to the given metering device 332 through a series of hops, and provided to the utility server 340 through the metering device poller 348.

During a power loss event, as explained with respect to FIGS. 1 and 2, the metering devices on the meter mesh network 336 can measure voltage on the corresponding power line. More specifically, each metering device, including the metering device 304, the metering device 332 and the metering device 334 include an energy storage element (e.g., the energy storage element 232 of FIG. 2). Thus, during a power loss event (e.g., a blackout or a brownout), each such metering device can continue to measure voltage on a corresponding power line during a backup interval of time (e.g., about 1 second to about 20 minutes).

Stated differently, the metering devices (including but not limited to the metering device 332, the metering device 304 and the metering device 334) of the meter mesh network 336 each include an energy storage element (e.g., the energy storage element 232 of FIG. 2) coupled to a metering module (e.g., the meter module 236 of FIG. 2) and a communication module (e.g., the communication module 240 of FIG. 2) of a system monitor (e.g., the system monitor 234 of FIG. 2 or the system monitor 116 of FIG. 1). The energy storage element of each such metering device provides backup power to the metering module and the communication module in response to a power flow on the powerlines (e.g., the powerlines 322) dropping below a first threshold for a time interval exceeding a second threshold (e.g., defined in the CBEMA curve), such that the metering module of a respective metering device of the meter mesh network 336 is configured to measure the power flow at a respective premises. Additionally, each such metering device of the meter mesh network 336 provides the power flow data for the backup interval of time and transmits the power flow data to a node on the meter mesh network during the interval of time, such as another metering device or the utility server 340.

The utility server 340 is a computing device (e.g., including a processor and a non-transitory memory) that can generate a map, such as a graphical map representing a region of premises that have metering devices on the meter mesh network 336, including the metering device 332, the metering device 304 and the metering device 334. The map (e.g., a heat map) generated by the utility server 340 characterizes regions of premises that have no power (e.g., a blackout). Additionally, the map generated by the utility server 340 characterizes regions of premises that have power at or above the first threshold and regions of premises that have power greater than 0 V and less than the first threshold. That is, the map characterizes premises that have reduced voltage.

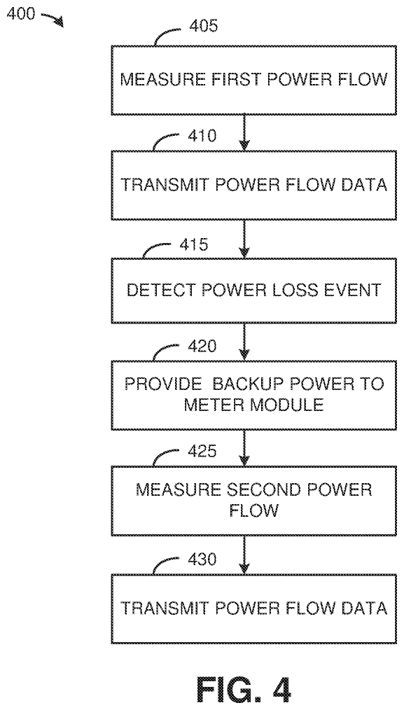

In view of the foregoing structural and functional features described above, an example method will be better appreciated with reference to FIG. 4. While, for purposes of simplicity of explanation, the example methods of FIG. 4 is shown and described as executing serially, it is to be understood and appreciated that the present examples are not limited by the illustrated order, as some actions could in other examples occur in different orders, multiple times and/or concurrently from that shown and described herein. Moreover, it is not necessary that all described actions be performed to implement a method.

FIG. 4 illustrates a flowchart of an example method 400 for monitoring power flow at a customer premises (e.g., the customer premises 106 of FIG. 1) downstream from a metering device (e.g., the metering device 100 of FIG. 1 and/or the metering device 200 of FIG. 2). Thus, the metering device is implemented with a smart meter or a smart meter collar. At 405, a metering module of a system monitor of the metering device that communicates on a meter network, measures a first power flow on powerlines for the premises and generates power flow data that characterizes power flow on a power line coupled to the premises. At 410, a communication module of the system monitor transmits the power flow data characterizing the first power flow to a node on a meter mesh network (e.g., the meter mesh network 336 of FIG. 3).

At 415, an energy storage element of the metering device detects a power loss event, such as a drop in a voltage on the powerlines to a level less than a first predetermined threshold for a interval of time greater than a second predetermined threshold. At 420, in response to detecting the voltage drop, the energy storage element provides backup power to the system monitor, which includes the metering module and the communication module. At 425, the metering module measures a second power flow for a backup interval of time following the voltage dropping below the first predetermined threshold for a time exceeding the second predetermined threshold of time. That is, the metering module continues to operate during the backup interval of time (e.g., about 1 second to about 20 minutes) during a power loss event (e.g., a blackout or a brownout). At 430, the communication module of the monitoring system transmits power flow data characterizing the second power flow to a node on the meter network during the backup interval of time following the voltage dropping below the threshold.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

What is claimed is:

1. A metering device for monitoring power flow at a premises, the metering device comprising:
a metering module that measures power flow on powerlines at a premises and provides power flow data characterizing the power flow on the powerline;
a communication module coupled to the metering module that transmits power flow data to a node on a meter network; and
an energy storage element coupled to the metering module and the communication module, wherein the energy storage element provides backup power to the metering module and the communication module in response to a voltage on the powerlines dropping below a first threshold for a time interval exceeding a second threshold, such that the metering module is configured to measure the power flow on the powerlines and provide the power flow data for a backup interval of time following the voltage dropping below the first threshold for a time exceeding the second threshold.

2. The metering device of claim 1, wherein the communication module is configured to transmit the power flow data to the node on the meter network for the backup interval of time follows the voltage dropping below the first threshold for the time exceeding the second threshold.

3. The metering device of claim 1, wherein the backup interval of time is at least 1 second.

4. The metering device of claim 1, wherein the backup interval of time is at least 1 minute.

5. The metering device of claim 1, wherein the energy storage element is a capacitor.

6. The metering device of claim 1, wherein the energy storage element is a battery.

7. The metering device of claim 1, wherein the first threshold and the second threshold are defined in the Computer Business Equipment Manufacturers Association (CBEMA) curve.

8. The metering device of claim 8, wherein the powerlines are coupled to a transformer and the power flow data during the backup interval of time characterizes a voltage signature of the power provided through the powerlines.

9. The metering device of claim 8, wherein the power flow data characterizes a voltage of the powerlines that is greater than 0 volts and less than the first threshold.

10. The metering device of claim 1, wherein the metering device is a smart meter collar installable between an electric meter and an inlet port of a premises.

11. The metering device of claim 1, wherein the metering device is a smart meter installable at an inlet port of a premises.

12. A system for monitoring power flow at a plurality of premises, the system comprising:
a meter network comprising:
a plurality of metering devices that each include an energy storage element coupled to a metering module and a communication module, wherein the energy storage element provides backup power to the metering module and the communication module in response to a voltage on corresponding powerlines dropping below a first threshold for a time interval exceeding a second threshold, such that the metering module of a respective metering devices of the plurality of metering devices is configured to measure the power flow at a respective premises and provide power flow data characterizing the measured power flow for a backup interval of time following the voltage dropping below the first threshold for the time interval exceeding the second threshold and the communication module transmits the power flow data to a node on the meter network during the backup interval of time; and
a utility server coupled to the meter network that receives the data from each of the plurality of metering devices.

13. The system of claim 12, wherein the utility server generates a map characterizing regions of premises that have power at or above the first threshold and regions of premises that have power greater than 0 volts and less than the first threshold.

14. The system of claim 13, wherein the map further characterizes regions of premises that have no power.

15. A method for monitoring power flow at a premises comprising:
measuring, by a metering module of a metering device that communicates on a meter network, a first power flow characterizing power on powerlines for a premises;
detecting, by the metering device, a drop in a voltage on the powerlines to a level less than a first threshold for an interval of time exceeding a second threshold;
providing, from an energy storage element to the metering device, backup power to the metering module and a communication module of the metering device in response to the detecting;
measuring, by the metering module, a second power flow on the powerlines during a backup interval of time following the voltage dropping below the first threshold for the interval of time exceeding the second threshold; and
transmitting, by the communication module, power flow data characterizing the second power flow measured by the metering module to a node on a meter network during the backup interval of time following the voltage dropping below the first threshold for the time interval exceeding the second threshold.

16. The method of claim 15, wherein the backup interval of time is at least 1 second.

17. The method of claim 15, wherein the backup interval of time is at least 1 minute.

18. The method of claim 15, wherein the energy storage element is a capacitor or a battery.

19. The method of claim 15, wherein the first threshold and the second threshold are defined in the Computer Business Equipment Manufacturers Association (CBEMA) curve.

20. The method of claim 15, wherein the metering device is a smart meter collar installable between an electric meter and an inlet port of a premises or a smart meter installable at an inlet port of a premises.
